(19) United States
(12) Patent Application Publication
(10) Pub. No.: US 2011/0048656 A1
(43) Pub. Date: Mar. 3, 2011

(54) BLIND DEVICE USING SOLAR CELLS

(75) Inventors: Moo Jung CHU, Daejeon (KR); Soo Young Oh, Daejeon (KR)

(73) Assignee: ELECTRONICS AND TELECOMMUNICATIONS RESEARCH INSTITUTE, Daejeon (KR)

(21) Appl. No.: 12/695,116

(22) Filed: Jan. 27, 2010

(30) Foreign Application Priority Data
Aug. 28, 2009 (KR) 2009-0080496

(51) Int. Cl. E06B 9/68; H01L 31/042

(52) U.S. Cl. 160/310; 136/244

(57) ABSTRACT

Provided is a blind device using solar cells. The blind device includes a plurality of solar cell panels, and a plurality of electric wires connecting the solar cell panels to each other in series. Each of the solar cell panels includes a first electrode and a second electrode on a surface, and a bypass device short-circuiting the first and second electrodes when light is not incident to the solar cell panel.

### CROSS-REFERENCE TO RELATED APPLICATIONS

This U.S. non-provisional patent application claims priority under 35 U.S.C. §119 of Korean Patent Application No. 10-2009-0080496, filed on Aug. 28, 2009, the entire contents of which are hereby incorporated by reference.

### BACKGROUND OF THE INVENTION

The present invention disclosed herein relates to a blind device using solar cells, and more particularly, to a blind device using solar cells, which improves the generating efficiency of the solar cells.

Recently, the importance of development of next generation clean energy resources is being emphasized because of issues such as the global warming due to carbon dioxide emission form fossil fuels, accidents of nuclear power plants, and radioactive contamination due to radioactive waste. Specifically, photovoltaic power generating systems (solar cells) using unlimited and semi-permanent sunlight are being regarded with much interest as next generation energy generating systems.

Such a solar cell is a semiconductor device that directly converts sunlight into electricity by using the photovoltaic effect in which light is irradiated on a semiconductor diode with p-n junction to generate electrons. The amount of voltage obtained from a unit solar cell is about 1 V or less, which is insufficient for any practical use. Thus, a solar cell module for generating power is manufactured by connecting a plurality of solar cells to each other in series and in parallel to generate predetermined voltage and current.

Such solar cell modules are extensively developed for various fields including plate type fixed generating facilities. For example, collapsible portable solar cell modules, curtains for adjusting light intensity, and blind devices including solar cells on blind slats to generate electricity have been developed. In this case, when solar cells are fully opened, a generating operation is effectively performed. However, when a portion of solar cells is collapsed or overlapped because of an insufficient space or the adjustment of light intensity, the portion shaded from light cannot generate electricity. When solar cells are connected to each other in series, a non-generating solar cell functioning as a resistor degrades the generating efficiency of a whole system, and heat generated from the non-generating solar cell may reduce the service life of the system and damage the system.

A bypass diode may be used in a typical plate type fixed solar cell module to form a circuit configured to bypass a solar cell having low generating capacity due to performance degradation or shadow. Typically, a unit solar cell has an electromotive force ranging from about 0.5 V to about 1 V, which is similar to a voltage drop value of a diode, so that it is inefficient to dispose a bypass diode on each cell. Thus, a bypass diode may correspond to a plurality of cells connected in series. In this case, voltage drop, which inevitably occurs in a diode, causes power loss through a bypass.

Specifically, in the case of a module including many slat type panels, such as a blind, when the panels respectively provided with bypass diodes overlap each other according to use condition, voltage drop occurs through the bypass diodes. When a bypass diode is attached to two or more slat type panels, some of the panels cause power loss and are heated according to overlapping state of the panels.

### SUMMARY OF THE INVENTION

The present invention provides a blind device using solar cells, which minimizes power loss.

Embodiments of the present invention provide blind devices using solar cells, the blind devices including: a plurality of solar cell panels; and a plurality of electric wires connecting the solar cell panels to each other in series, wherein each of the solar cell panels includes: a first electrode and a second electrode on a surface; and a bypass device short-circuiting the first and second electrodes when light is not incident to the solar cell panel.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a schematic view illustrating an interconnection structure of solar cell panels and a current flow according to embodiments of the present invention;

FIG. 2 is a cross-sectional view illustrating a blind device using solar cells, according to an embodiment of the present invention;

FIG. 3 is a cross-sectional view illustrating a blind device using solar cells, according to another embodiment of the present invention;

FIG. 4 is a cross-sectional view illustrating a blind device using solar cells, according to another embodiment of the present invention;

FIG. 5 is a cross-sectional view illustrating a blind device using solar cells, according to another embodiment of the present invention; and

FIGS. 6 through 8, and FIGS. 9A and 9B are schematic views illustrating applications of blind devices using solar cells, according to embodiments of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout.

In the following description, the technical terms are used only for explain a specific exemplary embodiment while not limiting the present invention. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

Additionally, the embodiment in the detailed description will be described with sectional views and/or plan views as ideal exemplary views of the present invention. In the figures, the dimensions of layers and regions are exaggerated for clarity of illustration. Areas exemplified in the drawings have general properties, and are used to illustrate a specific shape of a device. Thus, this should not be construed as limited to the scope of the present invention.

Hereinafter, a blind device using solar cells according to the embodiments of the present invention will now be described in detail with reference to the accompanying drawings.

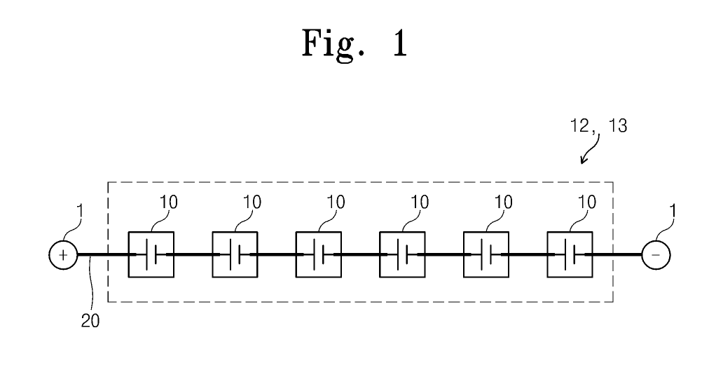

FIG. 1 is a schematic view illustrating an interconnection structure of solar cell panels 12 and 13 of a blind device according to an embodiment of the present invention. Referring to FIG. 1, the solar cell panels 12 and 13 include a plurality of solar cells 10. The solar cell panels 12 and 13 connect the solar cells 10 in series to generate large solar energy. The solar cell panels 12 and 13 are connected to external terminals 1 through electric wires 20 to supply energy generated from the solar cell panels 12 and 13 to an external device (not shown).

The solar cell 10 includes an n-type semiconductor and a p-type semiconductor that are attached to each other. When light is incident to the solar cell 10, the light is absorbed around a p-n junction interface to generate electron-hole pairs. Then, holes are moved to the p-type semiconductor, and electrons are moved to the n-type semiconductor through a built-in electric field, so as to generate a current. The current generated in the solar cell 10 receiving light flows through the solar cells 10. For example, the solar cell 10 may include one of silicon, cadmium telluride, copper indium gallium selenide (CIGS), copper indium selenide (CIS), gallium arsenide, optical absorption dyes, and organic semiconductors.

The blind device according to the current embodiment includes the solar cell panels 12 and 13. The solar cell panels 12 and 13 may include a generating panel (which is also denoted by 12) that receives light, and a non-generating panel (which is also denoted by 13) that does not receive light. Each of the solar cell panels 12 and 13 may include a bypass device to bypass the non-generating panel 13.

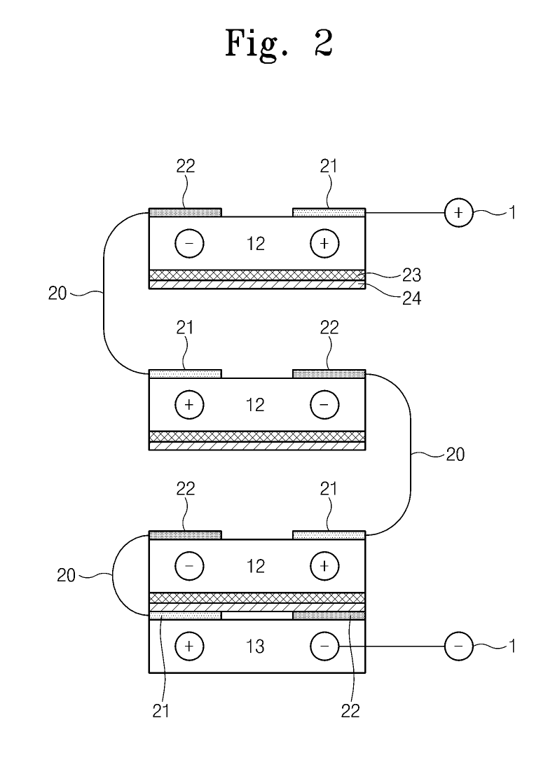

FIG. 2 is a cross-sectional view illustrating a blind device using solar cells according to an embodiment of the present invention.

Referring to FIG. 2, the blind device according to the current embodiment includes the solar cell panels 12 and 13, and the electric wires 20 electrically connecting the solar cell panels 12 and 13.

The solar cell panels 12 and 13 may be attached to plastic blind slats, or may constitute blind slats, respectively. Each of the solar cell panels 12 and 13 includes a bypass device 24 and first and second electrodes 21 and 22 that are spaced apart from each other on the front side of each of the solar cell panels 12 and 13. According to the current embodiment, conductive patterns functioning as the bypass devices 24 are disposed on the back sides of the solar cell panels 12 and 13.

The solar cell panels 12 and 13 are connected to each other in series through the electric wires 20. That is, the electric wires 20 may connect the first electrode 21 of one of the solar cell panels 12 and 13 to the second electrode 22 of another of the solar cell panels 12 and 13. The electric wires 20 may adjust the distances and the angles between the solar cell panels 12 and 13 to adjust the amount of incident light.

According to the current embodiment, the first and second electrodes 21 and 22 are embedded in the solar cell panels 12 and 13, and thus, their surfaces are flush with surfaces of the solar cell panels 12 and 13. According to the current embodiment, the first and second electrodes 21 and 22 may protrude to be reliably in contact with the conductive patterns functioning as the bypass devices 24.

When the solar cell panels 12 and 13 adjacent to each other are in contact with each other, the conductive patterns functioning as the bypass devices 24 short-circuits the first and second electrodes 21 and 22 of the non-generating panel 13 that does not receive light. That is, when the generating panel 12 is in contact with the non-generating panel 13, the generating panel 12 may cover a surface of the non-generating panel 13. The conductive pattern of the generating panel 12 may short-circuit the first and second electrodes 21 and 22 of the non-generating panel 13. The conductive pattern, which is formed of conductive material, may be adhered to the back sides of the solar cell panels 12 and 13 through insulating adhesives 23. Alternatively, the conductive pattern may be formed of conductive material having low resistance.

When light is incident to the solar cell panels 12 and 13 spaced apart from each other, the respective solar cell panels 12 and 13 generate electricity that flows to the external terminal 1 along the solar cell panels 12 and 13.

When the solar cell panels 12 and 13 adjacent to each other are in contact with each other, the non-generating panel 13, which is not exposed to light, does not generate electricity. At this point, the first and second electrodes 21 and 22 of the non-generating panel 13 are in contact with the conductive pattern 24 of the generating panel 12 to cause a short circuit. That is, the first and second electrodes 21 and 22 of the non-generating panel 13, and the conductive pattern 24 attached to the back side of the generating panel 12 form a bypass. Thus, according to the current embodiment, a generated current may bypass the non-generating panel 13 to flow to the external terminal 1.

That is, since the blind device according to the current embodiment includes a bypass bypassing the non-generating panel 13 through physical contact between the solar cell panels 12 and 13, a contact point having a sufficiently low resistance value is formed between the first and second electrodes 21 and 22. Accordingly, resistance increase due to a current path through the non-generating panel 13 can be prevented, and current bypass through the conductive pattern 24 can reduce voltage drop, relative to current bypass through a diode. Thus, loss of energy generated at the solar cell panels 12 and 13 is reduced to improve the generating efficiency of the solar cells.

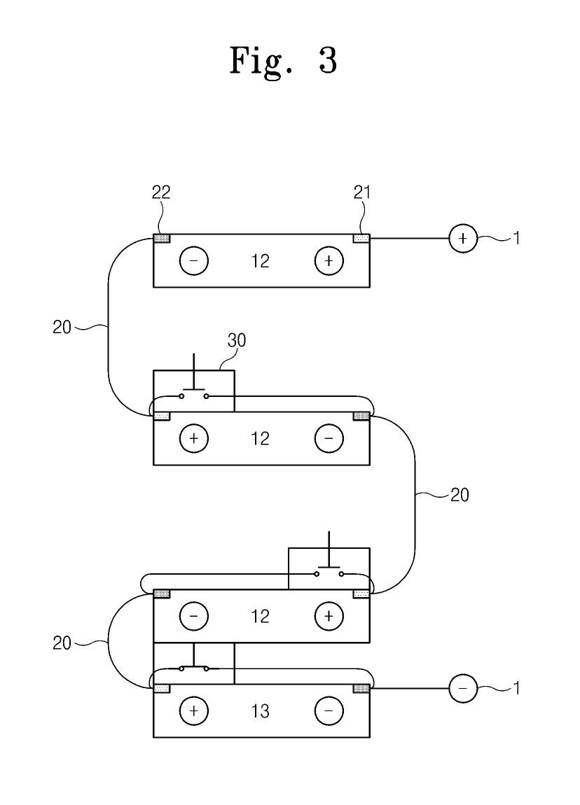

FIG. 3 is a schematic view illustrating a blind device using solar cells, according to an embodiment of the present invention.

Referring to FIG. 3, mechanical switches 30 as bypass devices are provided to the solar cell panels 12 and 13, respectively.

Each of the solar cell panels 12 and 13 includes the first and second electrodes 21 and 22 spaced apart from each other, and the mechanical switch 30 on a surface. For example, the mechanical switch 30 may be a push switch including a push button. The solar cell panels 12 and 13 are connected to each other in series through the electric wires 20. That is, the first electrode 21 of the generating panel 12 may be connected to the second electrode 22 of the non-generating panel 13 through the electric wire 20.

The electric wires 20 may adjust the distances and the angles between the solar cell panels 12 and 13 to adjust the amount of incident light.

The mechanical switches 30 may be turned on/off according to physical pressure generated by contact between the solar cell panels 12 and 13 adjacent to each other. The mechanical switch 30 between the first and second electrodes 21 and 22 of the solar cell panels 12 and 13 is connected in series to the first and second electrodes 21 and 22. The mechanical switches 30 are turned on by pressing force generated when the adjacent solar cell panels 12 and 13 are in contact with each other. When the adjacent solar cell panels 12 and 13 are spaced apart from each other, the pressing force is removed, so that the mechanical switches 30 are turned off.

The mechanical switches 30 are embedded in the solar cell panels 12 and 13, and thus, their surfaces are flush with surfaces of the solar cell panels 12 and 13. Alternatively, the mechanical switches 30 may protrude from the surfaces of the solar cell panels 12 and 13 such that the mechanical switches 30 are reliably in contact with the solar cell panels 12 and 13. Since the mechanical switches 30 have no conductive material exposed to the outside, external contamination, short circuits, and electric shocks are reduced.

According to the current embodiment, when light is incident to the solar cell panels 12 and 13 in the state where the solar cell panels 12 and 13 are spaced apart from each other, the solar cell panels 12 and 13 generate electricity. A generated current flows to the external terminal 1 along the solar cell panels 12 and 13 that are connected in series. When the solar cell panels 12 and 13 are in contact with each other, the non-generating panel 13 that is not exposed to light does not generate electricity, and the mechanical switch 30 is turned on by the contact between the solar cell panels 12 and 13. Accordingly, the first electrode 21, the mechanical switch 30, and the second electrode 22 form a bypass in the non-generating panel 13.

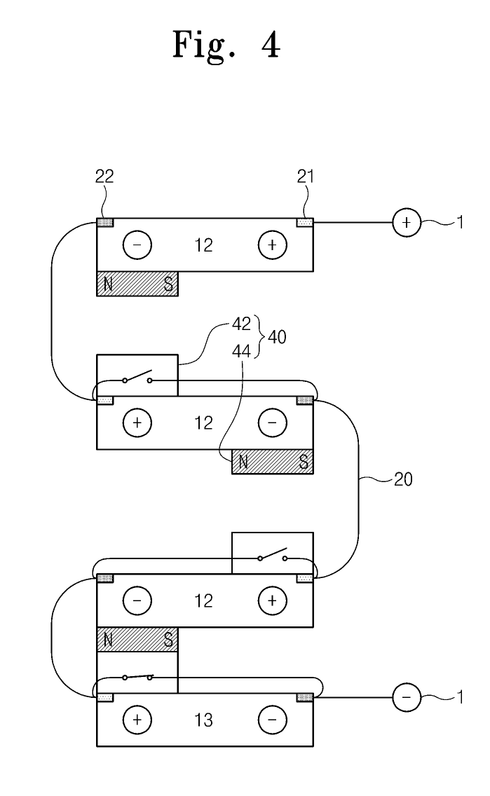

FIG. 4 is a schematic view illustrating a blind device using solar cells, according to another embodiment of the present invention.

Referring to FIG. 4, the blind device according to the current embodiment includes a bypass device 40 including a magnet switch 42 and a permanent magnet 44 on each of the solar cell panels 12 and 13. The magnet switch 42 reduces troubles due to repeated on/off operations of a switch, and inaccurate operations.

More particularly, each of the solar cell panels 12 and 13 includes, on its front side, the first and second electrodes 21 and 22 that are spaced apart from each other. The permanent magnet 44, generating a magnetic field having a predetermined intensity, may be attached to a surface of each of the solar cell panels 12 and 13, and the magnet switch 42 may be attached to another surface thereof. The magnet switch 42 may be disposed at an end portion of each of the solar cell panels 12 and 13, and the permanent magnet 44 may be disposed at another end portion thereof. The magnet switch 42 of one of the solar cell panels 12 and 13 adjacent to each other may face the permanent magnet 44 of another one.

The solar cell panels 12 and 13 may be connected to each other in series through the electric wires 20. That is, the first electrode 21 of the generating panel 12 is connected to the second electrode 22 of the non-generating panel 13 through the electric wire 20.

The magnet switch 42 has a structure in which a contact point is short circuited in a magnetic field and a current flows through the contact point. The region of the contact point is sealed to prevent the ingress of foreign substances. The magnet switch 42 is operated just by bring the solar cell panels 12 and 13 closer to each other without applying physical pressure. When the distance between the solar cell panels 12 and 13 is less than a predetermined value, the magnet switch 42 may form a bypass between the first and second electrodes 21 and 22 of the non-generating panel 13.

The permanent magnet 44 generates a magnetic field having a sufficient intensity for operating the magnet switch 42 adjacent to the permanent magnet 44. The permanent magnet 44 may include a magnetic field shielding member to prevent the magnetic field generated in the permanent magnet 44 from operating the irrelevant magnet switch 42 through the solar cell panels 12 and 13. The permanent magnets 44 of adjacent ones of the solar cell panels 12 and 13 are disposed on different vertical lines or different horizontal lines to prevent malfunctions of the magnet switches 42. In other words, the permanent magnets 44 of odd-numbered ones of the solar cell panels 12 and 13 may be disposed on first end portions of the solar cell panels 12 and 13, and the permanent magnets 44 of even-numbered ones of the solar cell panels 12 and 13 may be disposed on second end portions of the solar cell panels 12 and 13.

The permanent magnets 44 and the magnet switches 42 may be embedded in the solar cell panels 12 and 13, and thus, their surfaces are flush with surfaces of the solar cell panels 12 and 13. Alternatively, the permanent magnets 44 and the magnet switches 42 may protrude from the surfaces of the solar cell panels 12 and 13.

The solar cell panels 12 and 13 are connected to each other in series through the electric wires 20 that may adjust the distances and the angles between the solar cell panels 12 and 13.

According to the current embodiment, when light is incident to the solar cell panels 12 and 13 in the state where the solar cell panels 12 and 13 are spaced apart from each other, the solar cell panels 12 and 13 generate electricity. Generated currents flow to the external terminal 1 along the solar cell panels 12 and 13 that are connected in series.

When the solar cell panels 12 and 13 are in contact with each other, the non-generating panel 13 that is not exposed to light does not generate electricity, and the magnet switch 42 of the non-generating panel 13 is turned on by the permanent magnet 44 of the generating panel 12. Accordingly, the first electrode 21, the magnet switch 42, and the second electrode 22 form a bypass in the non-generating panel 13.

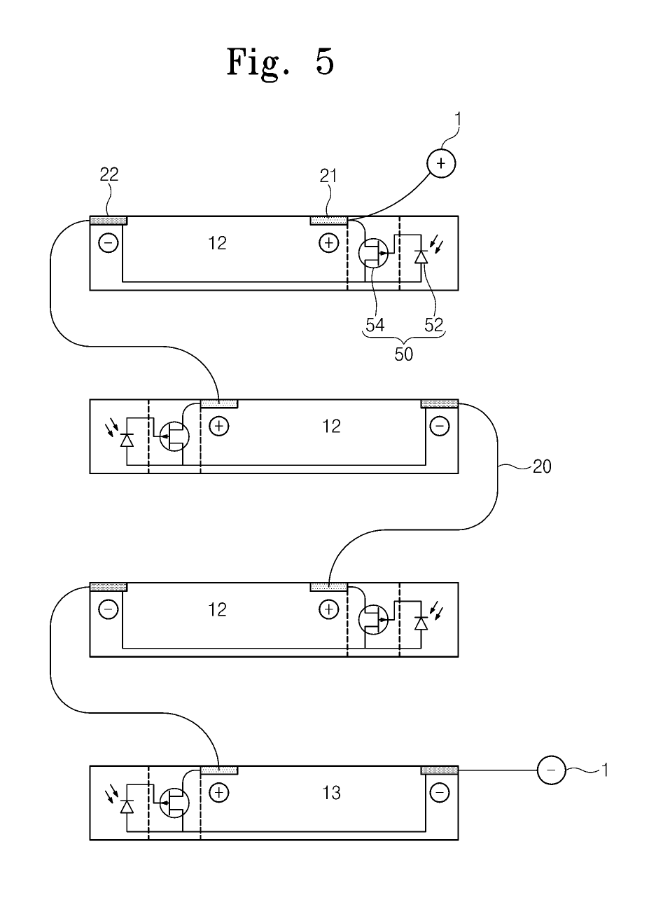

FIG. 5 is a schematic view illustrating a blind device using solar cells, according to another embodiment of the present invention.

Referring to FIG. 5, the blind device according to the current embodiment includes passive devices 52 and electrical switches 54, as bypass devices, at the solar cell panels 12 and 13. That is, according to the current embodiment, bypass devices 50 each may include the passive device 52 sensing light to control the operation of the electrical switch 54, and the electrical switch 54 controlled by the passive device 52.

In particular, the passive devices 52 may be photodiodes or phototransistors that use incident light to generate currents, or solar cells that are operated independently from the solar cell panels 12 and 13.

The electrical switch 54 is connected in series between the first and second electrodes 21 and 22, and is turned on/off by the passive device 52. For example, the electrical switch 54 may be a semiconductor device such as a relay and a transistor.

The passive device 52 and the electrical switch 54 may be discrete devices, or be integrated in a semiconductor chip.

The bypass devices 50 of the solar cell panels 12 and 13 may be disposed on vertical or horizontal lines that are different from each other. That is, the bypass devices 50 of odd-numbered ones of the solar cell panels 12 and 13 may be disposed on first end portions of the odd-numbered ones, and the bypass devices 50 of even-numbered ones of the solar cell panels 12 and 13 may be disposed on second end portions of the even-numbered ones.

According to the current embodiment, when light is incident to the solar cell panels 12 and 13 in the state where the solar cell panels 12 and 13 are spaced apart from each other, the solar cell panels 12 and 13 generate electricity. Generated currents flow to the external terminal 1 along the solar cell panels 12 and 13 that are connected in series.

The solar cell panels 12 and 13 are connected to each other in series through the electric wires 20 that may adjust the distances and the angles between the solar cell panels 12 and 13.

When the solar cell panels 12 and 13 are in contact with each other, light is not incident to the passive device 52 of the non-generating panel 13. The passive device 52, which does not receive light, turns the electrical switch 54 on to short-circuit the first and second electrodes 21 and 22 of the non-generating panel 13. That is, the first electrode 21, the electrical switch 54, and the second electrode 22 form a bypass in the non-generating panel 13.

The solar cell panels 12 and 13 are connected to each other in series through the electric wires 20 that may adjust the distances and the angles between the solar cell panels 12 and 13.

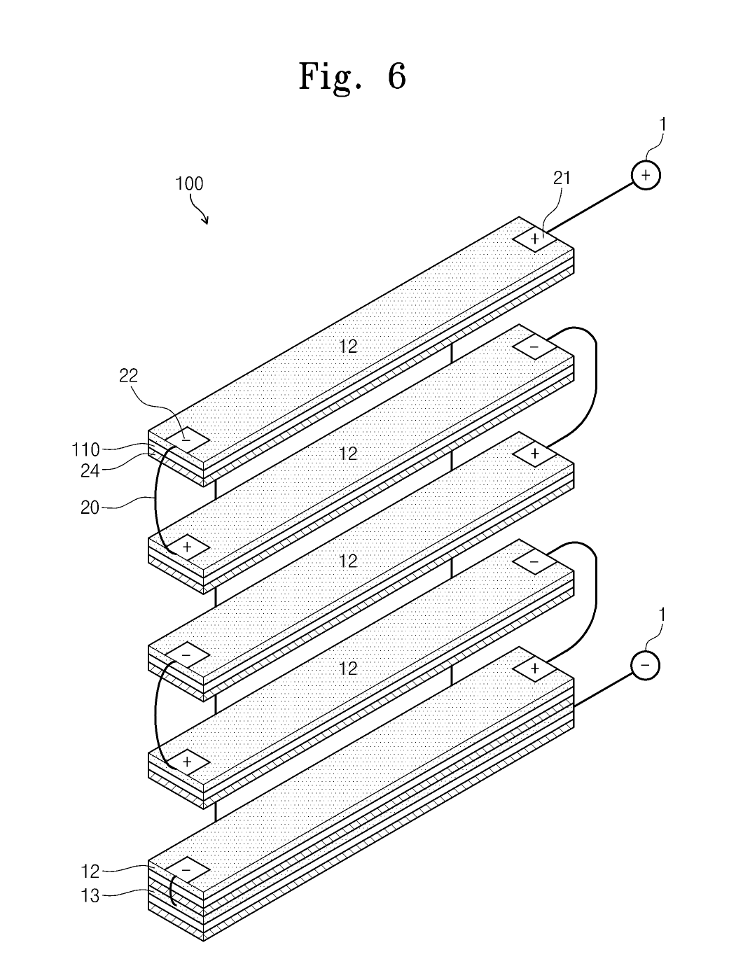

Hereinafter, applications of blind devices 100, 200, 300, and 400 using solar cells according to embodiments of the present invention will now be described with reference to FIGS. 6 through 8, and FIGS. 9A and 9B.

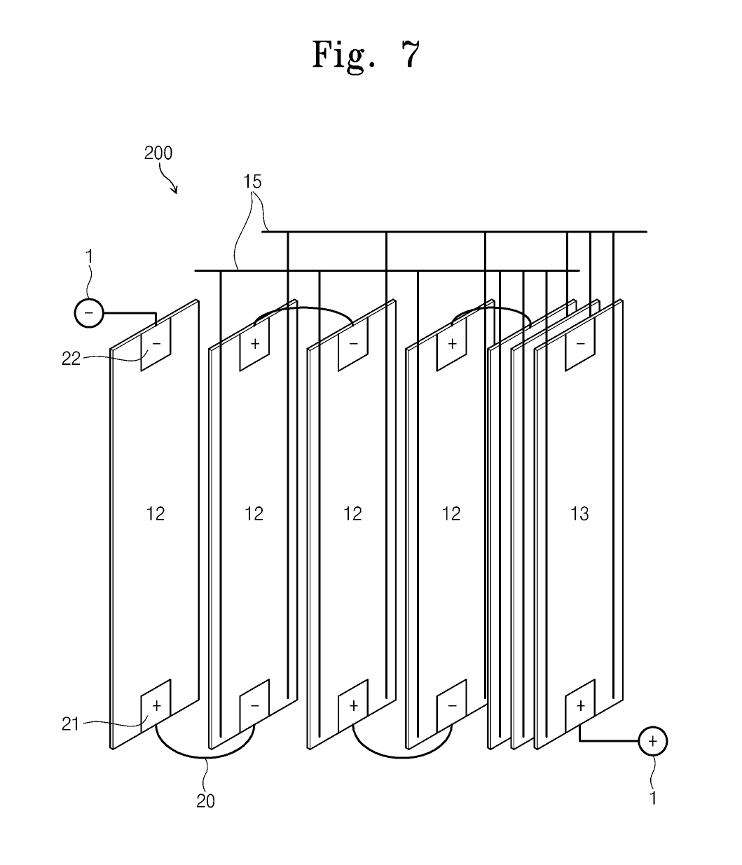

FIG. 6 is a schematic view illustrating the blind device 100 that is horizontally disposed. FIG. 7 is a schematic view illustrating the blind device 200 that is vertically disposed.

Referring to FIG. 6, the blind device 100 includes the solar cell panels 12 and 13 that are parallel to the ground. The solar cell panels 12 and 13 are connected to connection wires that adjust the length of the blind device 100 and the angles of the solar cell panels 12 and 13. That is, the connection wires are adjusted to vertically move and tilt the solar cell panels 12 and 13 at a predetermined angle. In addition, the connection wires may be the electric wires 20 electrically connecting the solar cell panels 12 and 13, and be connected to the external terminals 1.

Each of the solar cell panels 12 and 13 includes the first and second electrodes 21 and 22, and the bypass device 24.

The solar cell panels 12 and 13 may be attached to surfaces of blind slats 110, respectively. In this case, each of the solar cell panels 12 and 13 may be attached to the front surface of the blind slat 110, and the bypass device 24 may be attached to the rear surface of the blind slat 110.

When the solar cell panels 12 and 13 vertically move and cover a surface of the non-generating panel 13 disposed on the lower side, the non-generating panel 13 does not generate electrical energy. In addition, when the solar cell panels 12 and 13 vertically move, the adjacent solar cell panels 12 and 13 may be in contact with each other. Accordingly, the bypass device 24 of the generating panel 12 disposed on the upper side short-circuits the first and second electrodes 21 and 22 of the non-generating panel 13 disposed on the lower side. Thus, the current of the non-generating panel 13 flows to the generating panel 12 through the bypass device 24 without flowing through the solar cells.

Referring to FIG. 7, the blind device 200 includes the solar cell panels 12 and 13 that are vertical to the ground. The solar cell panels 12 and 13 are connected to connection wires that laterally move the solar cell panels 12 and 13 and adjust the angles of the solar cell panels 12 and 13. The solar cell panels 12 and 13 are connected to each other in series through the electric wires 20 that may be the connection wires adjusting the positions and angles of the solar cell panels 12 and 13.

When the adjacent solar cell panels 12 and 13 laterally move and overlap each other, the bypass device 24 short-circuits the first and second electrodes 21 and 22 of the non-generating panel 13 with a surface shaded from light. Thus, the current of the non-generating panel 13 flows to the generating panel 12 through the bypass device 24 without flowing through the solar cells.

When surfaces of the solar cell panels 12 and 13 are shaded from light, currents flow through the first and second electrodes 21 and 22 and the bypass devices 24 connected in series, without flowing through the solar cell panels 12 and 13 having the surfaces shaded from light.

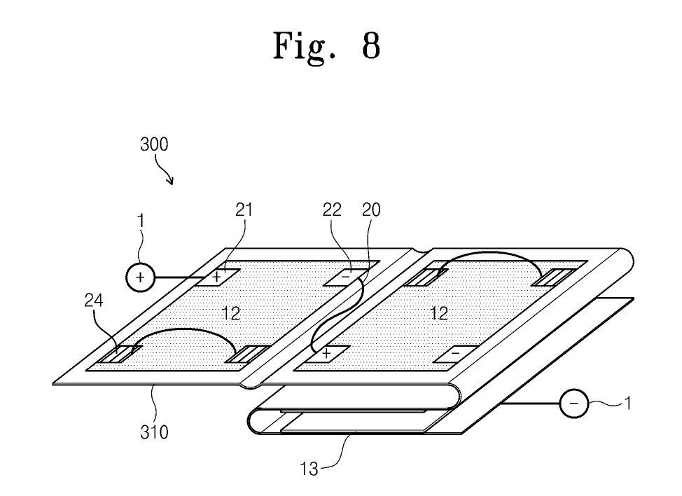

FIG. 8 is a schematic view illustrating the blind device 300 that is collapsible.

Referring to FIG. 8, the solar cell panels 12 and 13 of the collapsible blind device 300 may be completely opened when in use, and the solar cell panels 12 and 13 may overlap each other when not is use or partially in use.

The collapsible blind device 300 may include a plurality of blind slats 310 having outer surfaces to which the solar cell panels 12 and 13 are attached. The blind slats 310 adjacent to each other are connected to each other such that light incident surfaces of the solar cell panels 12 and 13 face each other.

The outer surfaces of the solar cell panels 12 and 13 are provided with the first and second electrodes 21 and 22 that are spaced apart from each other. Further, the outer surfaces of the solar cell panels 12 and 13 are provided with the bypass devices 24 that correspond to the first and second electrodes 21 and 22. That is, the first and second electrodes 21 and 22 of one of the solar cell panels 12 and 13 may face the bypass device 24 of the adjacent one of the solar cell panels 12 and 13.

When the blind slats 310 are opened, light is incident to the solar cell panels 12 and 13 of the collapsible blind device 300 to generate currents that flow to the external terminal 1 along the solar cell panels 12 and 13 connected in series.

When the blind slats 310 are collapsed, the bypass devices 24 short-circuit the first and second electrodes 21 and 22 of the adjacent solar cell panels 12 and 13, and currents generated from the generating panels 12 receiving light flow to the external terminal 1 through the bypass devices 24.

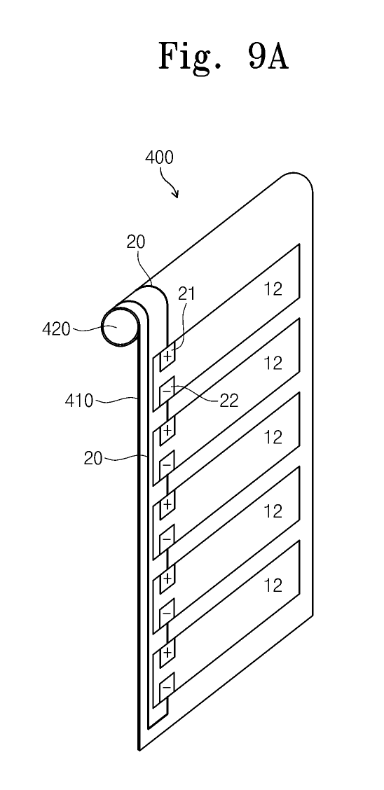

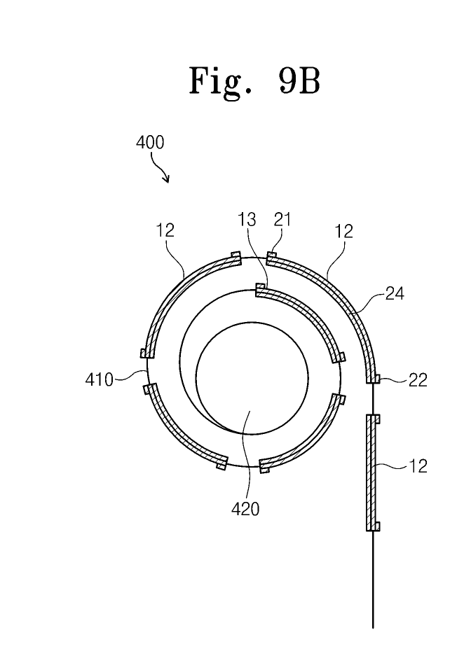

FIGS. 9A and 9B are schematic views illustrating the blind device 400 that is a roll type blind device.

Referring to FIGS. 9A and 9B, the blind device 400 includes a blind sheet 410 formed of flexible plastic or flexible fabric, and the solar cell panels 12 and 13 are attached to a surface of the blind sheet 410. A roller 420 is rotated to roll the blind sheet 410 up or down. The blind device 400 may include control wires to roll the blind sheet 410 up and down. The control wires may be the electric wires 20 connecting the solar cell panels 12 and 13 in series.

Each of the solar cell panels 12 and 13 includes the first and second electrodes 21 and 22, and the bypass device 24, and may be flexible to be rolled up together with the blind sheet 410.

When the blind sheet 410 is fully rolled down, light is incident to all of the solar cell panels 12 and 13 to generate currents that flow to the external terminal 1 along the solar cell panels 12 and 13 connected in series.

When the blind sheet 410 is partially rolled up, light is not incident to the non-generating panel 13 wound around the roller 420, and the vertically adjacent solar cell panels 12 and 13 may overlap each other. That is, the bypass device 24 short-circuits the first and second electrodes 21 and 22 of the non-generating panel 13 wound around the roller 420. Accordingly, currents generated from the solar cell panels 12 and 13 receiving light flow to the external terminal 1 through the bypass devices 24, without flowing through the non-generating panel 13.

According to the embodiments of the present invention, each of the solar cell panels constituting the blind device includes the bypass device to electrically connect only the generating panels receiving light to each other, thereby preventing power loss due to the non generating panels shaded from light.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A blind device using solar cells, the blind device comprising:
a plurality of solar cell panels; and
a plurality of electric wires connecting the solar cell panels to each other in series,
wherein each of the solar cell panels includes:
a first electrode and a second electrode on a surface; and
a bypass device short-circuiting the first and second electrodes when light is not incident to the solar cell panel.

2. The blind device of claim 1, wherein the bypass device is disposed on an opposite surface to the surface provided with the first and second electrodes, and is a conductive pattern having a length greater than a distance between the first and second electrodes.

3. The blind device of claim 2, wherein the conductive pattern of one of the solar cell panels adjacent to each other physically contacts the first and second electrodes of the other to which light is not incident.

4. The blind device of claim 1, wherein the bypass device is a mechanical switch connected in series between the first and second electrodes of the solar cell panel.

5. The blind device of claim 4, wherein the mechanical switch is turned on/off by contact between the solar cell panels adjacent to each other.

6. The blind device of claim 1, wherein the bypass device comprises:
a magnet switch connected in series between the first and second electrodes on the surface of the solar cell panel; and
a permanent magnet disposed on another surface of the solar cell panel.

7. The blind device of claim 6, wherein the magnet switch is disposed at an end portion of the solar cell panel, and the permanent magnet is disposed at another end portion of the solar cell panel, and
the permanent magnet of one of the solar cell panels adjacent to each other faces the magnet switch of the other.

8. The blind device of claim 7, wherein the magnet switch of the solar cell panel, a surface of which is shaded from light, is turned on/off using magnetic force variation between the permanent magnet and the magnet switch, according to a distance between the adjacent solar cell panels.

9. The blind device of claim 1, wherein the bypass device comprises:
a photo sensor sensing light; and
an electrical switch short-circuiting the first and second electrodes when the photo sensor does not sense light.

10. The blind device of claim 9, wherein the photo sensor is one of a solar cell, a photodiode, and a phototransistor.

11. The blind device of claim 9, wherein the electrical switch is one of a relay and a transistor.

12. The blind device of claim 9, wherein the bypass device is a single semiconductor chip in which the photo sensor and the electrical switch are integrated.

13. The blind device of claim 1, wherein the bypass devices of odd-numbered ones of the solar cell panels are disposed at first end portions of the odd-numbered ones, and
the bypass devices of even-numbered ones of the solar cell panels are disposed at second end portions of the even-numbered ones.

14. The blind device of claim 1, wherein the first and second electrodes is one of a metal plate protruding from an outer surface of the solar cell panel and a metal plate having an upper surface that is flush with the outer surface of the solar cell panel.

15. The blind device of claim 1, wherein the electric wires adjust a distance and an angle between the solar cell panels to control an amount of light incident through the blind device.

16. The blind device of claim 1, further comprising a plurality of blind slats,
wherein the solar cell panels are respectively attached to first surfaces of the blind slats, and
the bypass devices are respectively attached to second surfaces of the blind slats.

17. The blind device of claim 1, wherein sides of the adjacent solar cell panels are connected to each other such that light incident surfaces of the adjacent solar cell panels face each other,
the first and second electrodes, and the bypass device are disposed on the light incident surface of each of the solar cell panels.

18. The blind device of claim 1, further comprising:
a blind sheet to which the solar cell panels are attached; and
a roller coupled to the blind sheet to roll the blind sheet up or down,
wherein the bypass device short-circuits the first and second electrodes of the solar cell panel wound around the roller.
